(19) United States
(12) Patent Application Publication
(10) Pub. No.: US 2026/0319111 A1
(43) Pub. Date: Oct. 15, 2026

(54) Ionization Detector System with Fast Zeroing

(71) Applicant: Standard Imaging, Inc., Middleton, WI (US)

(72) Inventors: Eric Thomas Garz, Lodi, WI (US); William Edward Kolasa, Belleville, WI (US); Myles Lawton Sommerfeldt, Madison, WI (US)

(73) Assignee: Standard Imaging, Inc., Middleton, WI (US)

(21) Appl. No.: 19/629,213

(22) Filed: Mar. 26, 2026

Related U.S. Application Data
(60) Provisional application No. 63/786,697, filed on Apr. 10, 2025.

(51) Int. Cl. G01T 1/185; G01R 1/28; G01R 5/28; G01T 1/17

(52) U.S. Cl. CPC G01T 1/185; G01R 1/28; G01R 5/28; G01T 1/17

(57) ABSTRACT

An electrometer for use with ionization detectors tracks a rolling statistical value of received ionization data to capture an offset value for the electrometer when that variation drops below a predetermined threshold. This offset value is used to correct subsequent electrometer readings.

### CROSS REFERENCE TO RELATED APPLICATION

This application claims the benefit of U.S. application 63/786,697 filed Apr. 10, 2025, and hereby incorporated by reference.

### BACKGROUND OF THE INVENTION

The present invention relates generally to systems for measuring therapeutic radiation and, in particular, to an ionization detector system providing for fast zeroing of the electrometer.

Tumors and other medical conditions may be treated by high-energy radiation such as megavoltage radiation collimated and directed through a patient to a point of treatment. Such radiotherapy relies in part on the fact that tumor tissue is more sensitive than normal tissue to such high-energy radiation. Nevertheless, the radiation dose must be carefully controlled to limit the exposure of healthy tissue while ensuring sufficient radiation is received by the tumor.

Radiation flux may be determined using an ionization detector system which works by measuring current through an ionized gas between voltage-biased electrodes. The ionization detector system normally includes an ionization probe that may be attached to a sensitive electrometer that can measure current or accumulated charge. Ionization detectors are advantageously reusable and can provide real-time radiation measurement of a variety of different types of radiation and different energies.

The amount of current through the ionization probe may be extremely small (on the order of picoamperes) and the measured signal typically includes an offset, the latter being a function of variations in circuitry, humidity, temperature, component values, leakage currents, and the like. For this reason, prior to use of the ionization detector system, a zeroing process is typically performed where readings are acquired without the presence of radiation over a period of time that is long enough for the offset to stabilize and be sufficiently characterized. When the ionization detector system is set up and turned on, it is not untypical to wait 30 seconds or more before measurements can be performed. When multiple measurements characterizing different portions of the radiation beam or different beam positions need to be made, this time delay significantly delays calibration.

### BRIEF SUMMARY OF THE INVENTION

The present inventors have recognized that the stability of the offset value can be accurately anticipated by monitoring the short-term variation in the received signal. This allows the zeroing process to completed as soon as these short-term variations indicate stabilization has been obtained prior to the typical waiting interval. The result is a significantly faster zeroing process that allows improved efficiency in making radiation measurements.

These particular objects and advantages may apply to only some embodiments falling within the claims and thus do not define the scope of the invention.

### BRIEF DESCRIPTION OF THE DRAWINGS

FIG. 1 is a simplified block diagram of an ionization detector system, including an ionization probe and electrometer, the latter incorporating current measurement circuitry and an electronic computer including a memory holding a stored program for statistical calculation;

FIG. 2 is a time domain plot of an example signal from the ionization probe as processed by the electrometer showing calculation of one statistical measure of deviation in successive time windows; and

FIG. 3 is a flowchart of the program of FIG. 1.

### DETAILED DESCRIPTION OF THE PREFERRED EMBODIMENT

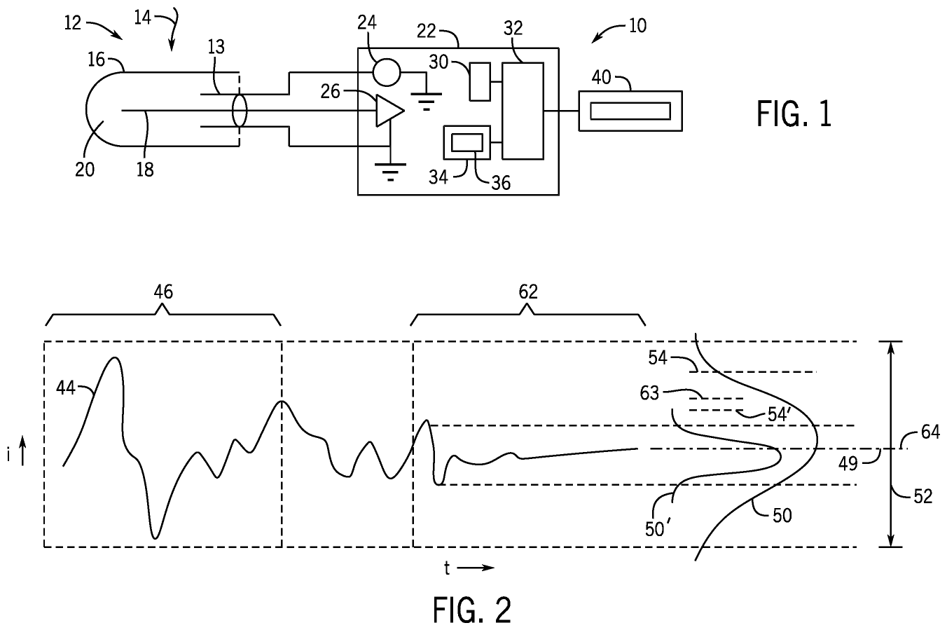

Referring now to FIG. 1, an ionization detector system 10 may provide an ionization probe 12 for receiving ionizing radiation 14, for example, from a radiotherapy machine (for example, an ionization chamber) or from a brachytherapy seed prior to implanting (for example, a well chamber), or the like. Generally the ionization probe 12 will provide an independent first electrode (shield) 16 and second electrode (collector) 18 separated by an ionizable gas 20. The ionization probe 12 operates to generate electrical current between the first electrode 16 and second electrode 18 when those electrodes are biased by an electrometer (internal or external) providing an electrical voltage, and the gas is ionized by radiation. A guard electrode 13 is used to reduce leakage current and provide a uniform electrical field in a defined volume and may be connected to ground.

The electrodes 16 and 18 of the ionization probe 12 may communicate with an electrometer 22, the latter providing a biasing circuit 24, for example, having an output terminal connected to the second electrode 18 to impose a biasing voltage on the second electrode 18 with respect to the electrode 16. Typically this internal or external biasing voltage will have a magnitude of as much as 450 V and, for example, be adjustable in ranges of −1000 V to −10 V or 10 V to 1000 V.

A transimpedance or charge digitizing amplifier 26 or the like may receive current from the second electrode 16 at a ground-referenced input to provide current or charge measurements. Typical measurement ranges include those listed in the following Table I, but single range measurements are also available on more basic electrometers, while more complex measurements are also available for FLASH radiation applications.

TABLE I

CURRENT
Low Range 0.001 pA-1000.00 pA, 1 fA resolution
High Range 0.001 nA-1.0 uA, 1 pA resolution
CHARGE:
Low Range 0.001 pC-100 mC, 1 fC resolution
High Range 0.001 nC-100 C, 1 pC resolution

It will be understood generally that charge values may be derived from current values through an integration of current over time.

The output of the amplifier 26 may be received by an analog-to-digital converter 30 whose digital output is input to a processor 32. The processor 32 may also communicate with an electronic memory 34 holding a stored program 36 as will be described below. The processor 32 may further communicate with the user interface panel 40 or through a communication protocol typically referred to as an API interface, for example, for displaying charge or current values and for accepting input from a user as will be discussed below in the description of the program 36.

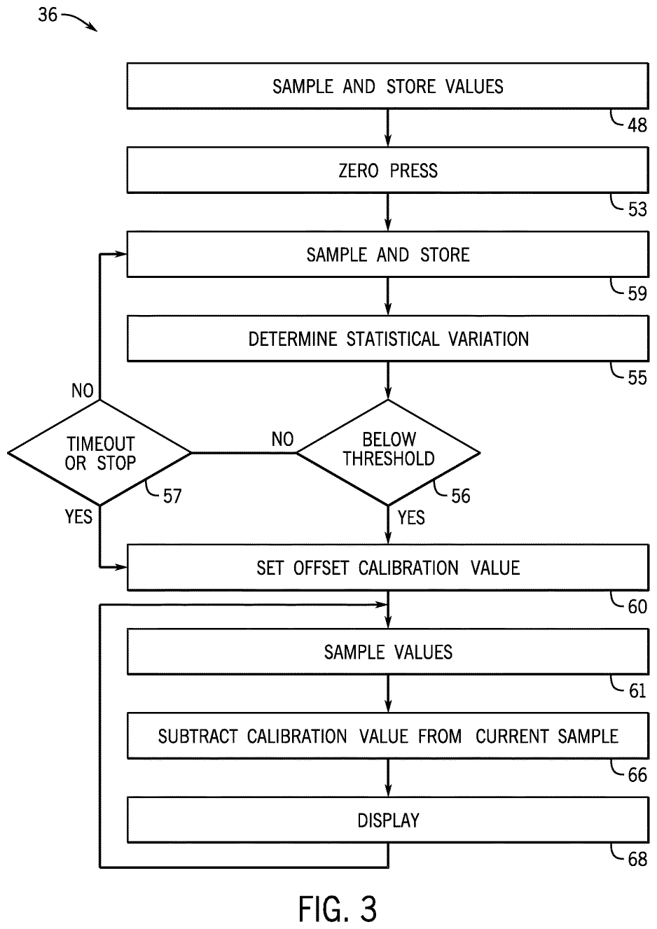

Referring now to FIGS. 2 and 3, the processor 32 may execute the program 36 to acquire the sample data 44 of the analog-to-digital converter 30 on a regular basis and store this in memory to define a rolling window 46 per process block 48. Generally, the rolling window will be of a fixed duration, for example, 60 seconds, of samples taken at 10 samples per second (which may be adjustable), with the latest point in the rolling window 46 tracking the latest acquired data.

The data of the window 46 may be statistically processed, for example, to compute a distribution 50 being a histogram of the number of samples in a set of ranges of electrical current values plotted against the electrical current values of those ranges. Typically, when the ionization probe 12 is not being irradiated, this distribution will approximate a Gaussian distribution reflecting a random variation of the sample data 44 about an offset value caused by thermal and electrical noise from various sources.

Per process block 53, after the ionization detector system 10 is set up and turned on, it may be either automatically triggered before beginning a collection or some other internal operation or the user may press an operator implemented on the user interface panel 40 providing a signal to the processor 32 to trigger a “zeroing” of the electrometer 22. Samples continue to be taken as indicated by process block 59.

At this time, per process block 55, the latest predetermined distribution 50 for the current window 46 is used to determine if the variation is below the threshold 56 of the sample data 44. In one embodiment, this variation measurement 54 is characterized by a statistical standard deviation of the distribution 50; however, it will be appreciated that other statistical variation measurements may be made including, for example, a maximum range of excursion during the window 46 (maximum value minus minimum value) or the like.

As indicated by decision block 56, the variation measurement 54 may be compared to a predetermined variation threshold 63 empirically determined to indicate that the sample data 44 has settled sufficiently to allow a meaningful offset value to be acquired. For example, the predetermined variation value 63 may be one standard deviation or a fraction thereof or, in the case of a maximum range of excursion, a given percentage of the average value 49 of the sample data 44 during the time window 46. In some embodiments, the user may enter data indicating for example, a bias voltage, the type (e.g., model number) of the ionization detector, the length of the cable, etc., and the threshold 63 may be a function of this entered data for example as stored in a lookup table.

If the variation measurement 54 is greater than the predefined threshold, the program proceeds to decision block 57 to see if the timeout value (for example, 40 seconds) has been reached or if the user has indicated that the calibration time should stop. If not, the program loops back to process block 59. If the timeout value has been reached at decision block 57, the program proceeds to process block 60 described below. Because the variation 50 is calculated repeatedly as new data comes in, even with a window as long as 60 seconds, the zeroing process triggered at decision block 56 may occur rapidly, often in much less than one second, after zeroing is initiated at process block 53 to be essentially instantaneous.

At a later time, for example, represented by window 62, a smaller variation measurement 54′ of a distribution 50′ may be calculated within the predetermined variation threshold 63. In this case, at decision block 56, the program proceeds to process block 60 where an automatic zeroing is performed by extracting an offset value 64 from the latest window (for example, window 62). This offset value may be the last sample in the window 62 or may be an average or a first moment of the distribution 50′ as two non-limiting examples.

At process block 61, additional sample data 44 is obtained and at process block 66, this offset value is then subtracted from the sample data 44 going forward to provide an adjusted output reflective of the amount of ionizing radiation 14 free from offset internal or external bias in the circuitry and equipment. These offset free values may then be displayed per process block 68 and this process repeated as new sample data 44 is received.

It will be appreciated that the steps of extracting statistical variation and applying a threshold may be performed using conventional computer programming steps or may be implemented through machine learning or the like trained to identify an appropriate stabilization of the signal based on inherent analysis of statistical variation and thresholding. For example, such a machine learning system may be trained with a teaching set of example signals linked to a binary value indicating whether an offset can be calculated from a given sample of a signal. Accordingly, the terms “processor” and “stored program” and the like should be understood broadly to encompass a variety of computer circuitry and programming techniques.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

References to “a microprocessor” and “a processor” or “the microprocessor” or cloud computing and “the processor,” can be understood to include one or more microprocessors or programmable digital device such as a FPGA that can communicate in a stand-alone and/or a distributed environment(s), and can thus be configured to communicate via wired or wireless communications with other processors, where such one or more processor can be configured to operate on one or more processor-controlled devices that can be similar or different devices. Furthermore, references to memory, unless otherwise specified, can include one or more processor-readable and accessible memory elements and/or components that can be internal to the processor-controlled device, external to the processor-controlled device, and can be accessed via a wired or wireless network.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. An electrometer acquisition system for an ionization radiation detector comprising:
a bias voltage circuit providing a bias voltage output for biasing an ionization type sensor having a shield and collector electrode separated by an ionizable gas for generating a predetermined current between the first and second electrodes for a given radiation level when the bias voltage is applied across the shield and collector electrodes;
a current sensor for receiving current from the ionization type sensor to provide a current measurement value; and
a processor executing a stored program to:
(a) receive digital representations of the current measurement value over time;
(b) extract a statistical variation of the digital representations during a predetermined time window;
(c) when the statistical variation drops below a threshold, extract an offset value of the digital representation within the statistical variation; and
(d) during a second predetermined time window different from the first predetermined time window, subtract the offset value from the digital representation during the second time window to output a baseline corrected ionization sensor value.

2. The electrometer system of claim 1 wherein the extracted offset voltage is selected from a mean of the digital representations during the predetermined time or a last value of the digital representations during the predetermined time.

3. The electrometer system of claim 1 wherein the threshold is a predetermined proportion of a deviation of the statistical variation or a maximum variation as a percentage of an average value.

4. The electrometer system of claim 1 wherein the processor initiates a performance of (b) upon receipt of a user command.

5. The electrometer system of claim 1 wherein the bias voltage has a magnitude in excess of 10 V.

6. The electrometer system of claim 1 wherein the electrometer system receive user input indicating at least one of a biasing output voltage, an ionization detector type, amplifier type, and a connecting cable length and the threshold is a function of the user input.

7. The electrometer system of claim 1 wherein the processor further monitors a time value after initiation of the performance of (b) and performs steps (c) and (d) without the statistical variation dropping below the threshold when the time value exceeds a predetermined time limit.

8. The electrometer system of claim 7 wherein the predetermined time limit is in excess of 30 seconds.
